(19) United States
(12) Patent Application Publication
(10) Pub. No.: US 2015/0023857 A1
(43) Pub. Date: Jan. 22, 2015

(54) PIEZOELECTRIC AND ELECTRORESTRICTOR MATERIALS

(71) Applicants: Massachusetts Institute of Technology, Cambridge, MA (US); Central Michigan University, Mt. Pleasant, MI (US); Robert Bosch LLC Research and Techology Center, Broadview, IL (US)

(72) Inventors: Rickard Roberto ARMIENTO, Linkoping (SE); Gerbrand CEDER, Wellesley, MA (US); Marco FORNARI, Mt. Pleasant, MI (US); Geoffroy HAUTIER, Bruxelles (BE); Boris KOZINSKY, Waban, MA (US)

(73) Assignees: Massachusetts Institute of Technology, Cambridge, MA (US); Central Michigan University, Mt. Pleasant, MI (US); Robert Bosch LLC Research and Technology Center, Broadview, IL (US)

(21) Appl. No.: 14/331,792

(22) Filed: Jul. 15, 2014

Related U.S. Application Data
(60) Provisional application No. 61/846,685, filed on Jul. 16, 2013.

(51) Int. Cl. H01L 41/187; G06F 19/00

(52) U.S. Cl. CPC H01L 41/1878; H01L 41/1871; H01L 41/1873; G06F 19/704
USPC 423/263; 423/598; 423/600; 423/594.8; 703/2

(57) ABSTRACT

One embodiment provides a method, comprising: calculating, using at least one computer, a distance to a hull for an alloy XₓY₁₋ₓ in the range 0.01≦x≦0.99, where X and Y are perovskite materials; determining, using the at least one computer, a preferred phase for the alloy in the range 0.01≦x≦0.99; and selecting an alloy composition having the distance to the hull being less than 0.1 eV/atom and for which the preferred phase in at least a portion of the range 0.01≦x≦0.99 is a tetragonal phase. Piezoelectric materials as selected by the method are also provided.

CROSS-REFERENCE TO RELATED PATENT APPLICATIONS

This application claims priority from U.S. Provisional Application Ser. No. 61/846,685, filed Jul. 16, 2013, which is incorporated herein by reference in its entirety.

### BACKGROUND

Materials with high piezoelectric coefficients are of technological interest. The large piezoelectric effect in lead zirconate titanate (PZT)-based compounds has generated much attention, and recent research has sought to replace PZT with an environmentally friendly, lead-free, substitute with similar properties. Two lead-free isovalent alloy systems have been previously identified (K, Na, Li)(Nb, Ta)O₃ and Ba(Ti_{0.8}Zr_{0.2})O₃—(Ba_{0.7}Ca_{0.3})TiO₃. While these materials show a similar phase boundary as PZT, which is important for a high piezoelectric effect, the former material is expensive and difficult to synthesize due to problems with vaporization of potassium oxide during sintering, and the latter has a phase boundary that is very temperature dependent. The identification of new alloy compounds that reproduce the desirable properties of PZT is a well-defined challenge.

### SUMMARY

In view of the foregoing, the Inventors have recognized and appreciated the advantages of a method of selecting piezoelectric alloy compositions.

Provided in one embodiment is a piezoelectric material including at least one of (Ba₁—Sn₁)Ti₂O₆, (Ba₃—Sn₁)Ti₄O₁₂, (Ba₃—Sn₅)Ti₈O₂₄, Ba₄(Hf₃—Ti₁)O₁₂, (Ba₅—Sn₃)Ti₈O₂₄, (Ba₇—Sn₁)Ti₈O₂₄, Ba₈(Hf₇—Ti₁)O₂₄, Ba₈(Sn₇—Ti₁)O₂₄, Bi₄(Al₁—Ga₃)O₁₂, Bi₄(Ga₃—Sc₁)O₁₂, Bi₈(Al₁—Ga₇)O₂₄, Bi₈(Al₃—Ga₅)O₂₄, Bi₈(Ga₅—Sc₃)O₂₄, Bi₈(Ga₇—Sc₁)O₂₄, (Ca₁—Sn₃)Ti₄O₁₂, (Cs₁—Na₇)Nb₈O₂₄, (Cu₁—K₇)Nb₈O₂₄, (Cu₁—K₇)Ta₈O₂₄, (Ga₁—K₃)Ta₄O₁₂, (K₁—Rb₁)Ta₂O₆, (K₁—Rb₃)Ta₄O₁₂, (K₁—Tl₁)Ta₂O₆, (K₃—Rb₅)Ta₈O₂₄, (K₃—Tl₁)Ta₄O₁₂, (K₅—Rb₃)Ta₈O₂₄, (K₅—Tl₃)Ta₈O₂₄, (Li₁—Rb₇)Nb₈O₂₄, (Na₅—Rb₃)Nb₈O₂₄, (Sn₁—Sr₁)Ti₂O₆, (Sn₁—Sr₃)Ti₄O₁₂, (Sn₁—Sr₇)Ti₈O₂₄, (Sn₃—Sr₁)Ti₄O₁₂, (Sn₃—Sr₅)Ti₈O₂₄, (Sn₅—Sr₃)Ti₈O₂₄, (Sn₇—Sr₁)Ti₈O₂₄, and Sr₈(Si₁—Ti₇)O₂₄.

Provided in another embodiment is a method, comprising: calculating, using at least one computer, a distance to a hull for an alloy XₓY₁₋ₓ in the range 0.01≦x≦0.99, where X and Y are perovskite materials; determining, using the at least one computer, a preferred phase for the alloy in the range 0.01≦x≦0.99; and selecting an alloy composition having the distance to the hull being less than 0.1 eV/atom and for which the preferred phase in at least a portion of the range 0.01≦x≦0.99 is a tetragonal phase.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIGS. 1(a)-1(d) depict a representation of the ideal perovskite crystal structure, a tetragonal distortion of the structure, a rhombohedral distortion of the structure, and a rotation along the (1, 1, 1) direction distortion of the structure in one embodiment.

FIG. 2 depicts a stability (upper graph) and energy preference for the TET distortion (lower graph) for the two component alloy PbTiO₃—PbZrO₃ (PZT) in one embodiment.

FIG. 3 depicts a stability (upper graph) and energy preference for the TET distortion (lower graph) for the BaTiO₃—BaZrO₃—CaTiO₃ alloy system in one embodiment.

FIG. 4 depicts a stability (upper graph) and energy preference for the TET distortion (lower graph) for the (K, Na)(Nb, Ta)O₃ alloy system in one embodiment.

FIG. 5 depicts a stability (upper graph) and energy preference for the TET distortion (lower graph) for various alloys having Li with the components of the (K, Na)(Nb, Ta)O₃ alloy system in one embodiment.

FIG. 6 depicts a stability (upper graph) and energy preference for the TET distortion (lower graph) for two-component alloys that remain after initial screening that contain Pb, other than PZT in one embodiment.

FIG. 7 depicts a stability (upper graph) and energy preference for the TET distortion (lower graph) for various perovskites with Cu introduced in one embodiment.

FIG. 8 depicts a stability (upper graph) and energy preference for the TET distortion (lower graph) for two-component alloys containing Si in one embodiment.

FIG. 9 depicts a stability (upper graph) and energy preference for the TET distortion (lower graph) for two-component alloys containing Sn in one embodiment.

FIG. 10 depicts a stability (upper graph) and energy preference for the TET distortion (lower graph) for two-component alloys containing Bi in one embodiment.

### DETAILED DESCRIPTION

Following below are more detailed descriptions of various concepts related to, and embodiments of, selecting piezoelectric alloy compositions. It should be appreciated that various concepts introduced above and discussed in greater detail below may be implemented in any of numerous ways, as the disclosed concepts are not limited to any particular manner of implementation. Examples of specific implementations and applications are provided primarily for illustrative purposes.

The morphotropic phase boundary (MPB) is a phase region in the temperature-composition phase diagram, where the macroscopic polarization vector quasicontinuously changes direction. This region produces the high piezoelectric coefficient in PZT, which occurs at nearly equal concentrations of PbZrO₃ (PZ) and PbTiO₃ (PT). A high-throughput framework for the computation of material properties of pure ternary perovskites may be used to identify a set of alloy endpoints with beneficial properties for forming an MPB. It is recognized that there is a need for expanding on the prior identification of alloy end-points by analyzing the possible solid solutions to search for any stable binary isovalent perovskite alloy that can form an MPB.

A method is provided for screening a large chemical space of perovskite alloys for systems with desirable properties to accommodate a morphotropic phase boundary (MPB) in their composition-temperature phase diagram—such a feature may produce a high piezoelectric performance. Alloy end-points may be identified in a high-throughput computational search. An interpolation scheme may be used to estimate the relative energies between different perovskite distortions for alloy compositions with a minimum of computational effort. Identified alloys may be further screened for thermodynamic stability. The screening may identify alloy systems already known to host a MPB, or alloy systems that may be promising candidates for future experiments. The methods described herein may be applied to other perovskite systems, e.g., (oxy-)nitrides, and may provide a useful methodology for any application of high-throughput screening of isovalent alloy systems.

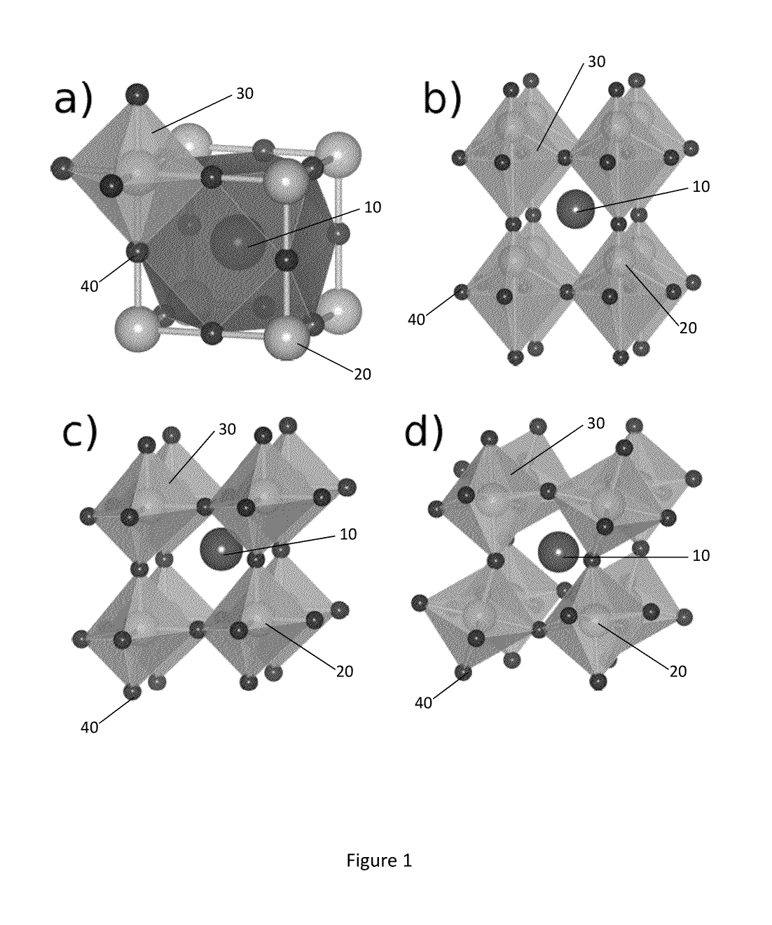

In one embodiment, the methods described herein are applied to the perovskite crystal structure, as it is known from PZT materials that this structure may accommodate a phase-change driven polarization rotation that is coupled to strain. Screening for alloy end-points may use two primary criteria connected to the appearance of an MPB in an isovalent alloy system. First, each alloy endpoint may be an insulator or semiconductor with a suitably large band gap to avoid current leakage. This criteria may be realized by selecting compounds with a quite generous limit on the minimum Kohn-Sham band gap, Δ_{KS}>0.25 eV. Furthermore, three main distortions of the ideal perovskite cell may be considered: tetragonal (TET), rhombohedral (RHO), and alternating clockwise and anticlockwise octahedral rotation (ROT) around the (1, 1, 1) direction. The ideal perovskite crystal structure and the considered distortions are illustrated in FIG. 1. In one embodiment, the second screening criteria may be a limit on the difference in the lowest and highest formation energy of these distortions, i.e., that

ΔE^{P}=max(E_{ROT}, E_{TET}, E_{RHO})−min(E_{ROT}, E_{TET}, E_{RHO})<1.00 eV (1)

The motivation for limiting the energy difference is that it may produce a small energy barrier between phases, allowing for a MPB.

FIG. 1 depicts the ideal perovskite crystal structure (a) and the three main distortions (b-d) in one embodiment. The ideal perovskite structure ABO₃ has a 12-coordinated A-site cation 10 and 6-coordinated B-site cations 20, embedded in octahedra 30 defined by oxygens 40. The distorted phases are (b) tetragonal (TET), (c) rhombohedral (RHO), and (d) rotations along the (1, 1, 1) direction (ROT). For illustrative purposes, the magnitude of the distortions depicted in FIGS. 1(b)-(d) are exaggerated compared to typical values.

Screening identified a set of 49 pure perovskite systems that may be used as alloy end-points. If alloys of up to four different such endpoints are considered, the number of possible alloys would be 49⁴=5,764,801. These alloys may then be considered over a large set of relative composition ratios, resulting in a very large configuration space. Screening this vast space may be accomplished by utilizing an interpolation scheme based on computed phase energies for distorted phases of the pure alloy end-points to predict the energetics of a possible combination without additional time-consuming computation. The interpolation scheme may be used to identify two component perovskite compositions that at some mixing ratio prefer a TET distortion (i.e., compositions that in this respect are similar to PT). Previously identified MPBs in perovskites appear in the region between such a TET distorted phase and one of the other distortions. For any combination of two perovskites that is predicted by the interpolation to favor TET distortion in its zero temperature ground state at any mixing ratio, all mixing ratios that are possible to realize in a 40-atom supercell may be investigated (i.e., concentrations in steps of 1/8). By comparing computed energies of these systems with those of competing phases the stability of each realized mixing ratio may be determined. A stable TET material may provide an opportunity for an MBP through further adjustment of the alloying ratio to reach equilibrium between distorted phases.

### Interpolation of Alloy Properties

Previously conducted high-throughput screening of alloy endpoints has produced a large database of energies for the various distorted phases of perovskites at various unit cell volumes, computed by density functional theory (DFT). DFT has generally been successful in describing the properties of ferro- and piezoelectric perovskite compounds. Calculations may be performed utilizing any software, such as a commercially available software. According to one embodiment, the calculations may be performed utilizing the Vienna ab inito simulation package (V_{ASP} 5.2.2) with projector augmented wave pseudopotentials (PAWs) and the exchange-correlation functional. For systems with TET and RHO distortion the internal degrees of freedom may be relaxed to find the minimum energy structure allowed by the respective symmetry (i.e., the tilt and c/a ratio respectively, as well as other ionic displacements allowed by the symmetry). The phase energy of a distorted phase of any alloy may be estimated based on these computed energies.

A linear interpolation between the phase energies of the distortions of the involved alloy end-points may be considered first. However, these phase energies depend on the cell volume, sometimes in a non-linear way. At a volume when a distorted phase becomes equal to the cubic phase (i.e., there is no longer an energy preference to distort the structure), the phase energy vs. volume curve of the distorted phase may join that of the cubic phase, leading to a sharp change in the derivative. One example of the importance of the volume dependence of the phase energies of alloy end-points is the PT-like material (Ba_{0.7}Ca_{0.3})TiO₃ in a known MPB alloy. Neither BaTiO₃ or CaTiO₃ are predicted to prefer a TET distortion at their respective relaxed volumes. Hence, a linear interpolation of the phase energies would not predict an alloy that prefers a TET distortion in this system. However, by taking into account that the larger cell volume of BaTiO₃ expands the volume of CaTiO₃, it is computed that for some alloy ranges the TET distortion is the lowest energy distortion. In at least this embodiment, it is noted that the volume dependence of the distorted phase energies should be taken into account.

The following interpolation scheme may be employed for an alloy XₓY₁₋ₓ between end-points X and Y at mixing ratio x. First, the resulting unit cell volume V may be estimated by linear interpolation from the cell volumes of X and Y in accordance with Vegard's law. Second, for each of the 49 suggested alloy end-points, a set of 11 computations spanning cell volumes from 45 to 90 Å may be performed. These pre-computed energies for X and Y may be employed to construct piecewise linear energy vs. volume curves for the two end-points separately, and to obtain the distorted phase energies at volume V. Finally, these end-point phase energies at volume V may be interpolated linearly to alloy ratio x to estimate the phase energies of the alloy XₓY₁₋ₓ.

A higher-order interpolation in the energy vs. volume curve may be considered to improve accuracy. However, as explained above, the curve may sharply change derivative at some points, and thus a piecewise linear interpolation may be a safer option.

As an example, the calculations involved in this interpolation scheme for the PZT alloy system will be described. For both PT and PZ, at 11 volumes in the range 45 to 90 Å, the energy of all three distortions, CUB, RHO and TET, were calculated. The number of calculations performed is thus 66. Only one calculation, each for RHO or TET distortions, is counted, but during these calculations the internal degrees of freedom are relaxed under the respective symmetry constraints, individually at each volume. Once these end point calculations are in place, the energy of, e.g., TET disordered PZT, may be estimated at, e.g., alloy ratio 0.5, as the average of the TET distorted PT and the TET distorted PZ end point energies at the volume predicted by Vegard's law. This example may suggest that the demand on alloy end-point calculations is rather heavy. Nevertheless, the number of end-point calculations scales as O(N) with N the number of endpoints considered, but makes available the study of O(N²) 2-component alloys. The same endpoint calculations may be used for interpolation of alloys of arbitrary order.

### Stability Screening

The interpolation scheme in the previous section may be used to identify alloys with any combination of energies of distorted phases without having to run computations for each separate alloy and composition ratio. In one embodiment, to experimentally synthesize an alloy, the thermodynamical instability of the alloy to be synthesized may not be too large. Screening for thermodynamical instability may be based on a zero temperature distance to the hull analysis using high-throughput phase diagram methods. According to one embodiment, the term ‘distance to the hull’ may refer to the energy difference between a phase and the most stable linear combination of competing phases at the same composition. This energy difference may be calculated by making a zero temperature phase diagram over all competing phases currently known, such as the phases reported in the materialsproject.org database. The convex hull that spans the formation energies of the known competing phases may be constructed and the hull distance may then be calculated as the difference between the formation energy per atom of the alloy and the value of the convex hull at the composition ratio of the alloy. For example, if the alloy under consideration is also the ground state phase at zero temperature, it forms a part of the convex hull, and the hull distance is zero. For example, a hull distance H>0 may indicate that there is a combination of known competing phases that would lower the formation energy at zero temperature by H.

A minor thermodynamical instability at zero temperature does not necessarily make alloy synthesis impossible. For example, an alloy with an instability at zero temperature may be synthesized if, e.g., the energy barriers to competing phases are large or if the entropy contribution sufficiently stabilizes the alloy. Hence, rather than outright dismissing compounds with nonzero hull distance, the distance to the hull may be utilized as an estimate of the probability for a specific alloy to synthesized, i.e., a higher hull distance indicates a successful synthesis is less likely. This may account for possible errors in the computational methods, metastability, and a reasonable entropy contribution at relevant temperatures. Based on the known predictability of these methods, and in particular, based on obtained values for known stable perovskite alloys, compounds are dismissed as unlikely to be synthesized when they are 0.1 eV/atom above the hull. For the contribution from inaccuracy in the computational methods at 0 K, a closer examination for ternary oxides indicates the standard deviation in formation energies is 0.024 eV/atom, thus 90% of errors should lie within 0.047 eV/atom.

To avoid under-predicting the distance to the hull, formation energies for as many competing phases as possible may be included. A pre-existing structure prediction tool may be employed to predict possible competing phases of each of the alloy end-points. The energies of all identified competing phases may be calculated. The structure prediction algorithm may not be absolutely exhaustive, and it is possible that some relevant competing phases may be overlooked. Thus it may be possible to predict certain alloys as thermodynamically stable, whereas a synthesis attempt would instead produce the omitted competing phase. An omitted competing phase will not result in the incorrect dismissal of an alloy system.

For each identified perovskite alloy that the interpolation scheme has predicted to prefer TET distortion at some mixing ratio, a DFT computation may be performed for all systems in the full range of mixing ratios for the A and B site that may be realized in a 40-atom supercell, i.e., in steps of 1/8, relaxed starting from a weakly TET distorted crystal (i.e., c/a=1.03). This starting point for the relaxation may produce the results below for stability vs. composition that specifically show the stability of the TET distortion. However, the energy difference between the distortions is generally small compared to that of competing phases, as expected due to the screening for end-points that have a limited energy difference between the distortions, i.e. ΔE^{P}<1.00 eV.

The ordering of different ions in the DFT computations may be chosen such that similar ions are placed as far apart as possible in the supercell. Due to the similarity in electrostatics and bonding between the ions in an isovalent alloy, the energy difference of different orderings is expected to be small on the energy scale of thermodynamical stability.

### Results

A pair of the 49 alloy end-points that have the same element on either the A or B site may be selected, and employed in the energy interpolation scheme to identify all pairs of alloy end-points for which the TET distortion has the lowest energy of the considered distortions, at some mixing ratio. Since 11 out of our 49 end-points already prefer the TET distortion in their pure phase, they will trivially generate TET alloys with very small amounts of any one of the other end-points. Alloys predicted to be TET only up to a very small ratio with another end-point (<1%) may be disregarded. This procedure produces 112 entries to be investigated for thermodynamical stability as described in the previous section.

In this embodiment (as shown by the analysis below), any alloy that, over all mixing ratios, exceeds a hull distance of 0.1 eV is dismissed without further investigation. Over the set of computations in the analysis it may be prohibitively difficult to reach stable convergence of the electron density for the computations of Rb(Nb, Ta)O₃ and (Rb, Cs)NbO₃, which has prevented further analysis of those alloy systems. These issues may not be fully remedied by straightforward adjustments of the computational parameters, e.g., replacing the pseudopotentials or slight changes of the convergence parameters. Since the cost of Rb makes it unlikely that Rb-based compounds may yield commercially viable piezoelectric materials, these systems were not pursued further.

The analysis produces 42 alloy systems to be investigated. Compounds known to exhibit an MPB were investigated first, and then the most interesting alloy systems found in the screening are discussed.

The screening may be performed by any suitable method. According to one embodiment, a screening method may be a method of selecting an alloy composition. The method may include calculating a distance to a hull for an alloy XₓY₁₋ₓ in the range 0.01≦x≦0.99 where X and Y are perovskite materials, calculating the preferred phase for the alloy in the range 0.01≦x≦0.99, selecting an alloy composition with a distance to the hull of less than 0.1 eV/atom and for which a preferred phase in at least a portion of the range 0.01≦x≦0.99 is the tetragonal phase. The calculating and selecting may be carried out utilizing at least one computer. According to one embodiment, the screening may be performed without considering the piezoelectric coefficient of the alloy.

The identified alloys may be produced utilizing any appropriate synthesis process. According to one embodiment, the identified alloys may be synthesized utilizing a ball milling process.

### The PZT System

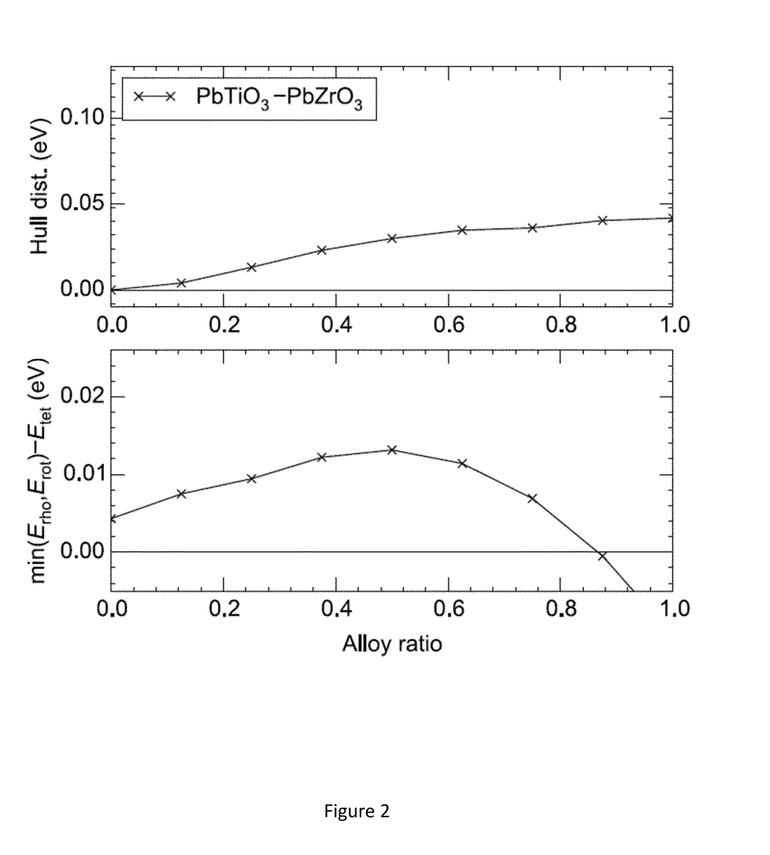

FIG. 2 depicts the distance to the hull and preference for a TET distortion of Pb(TiₓZr₁₋ₓ)O₃. This prototypical piezoelectric system serves as an example of the above described analysis methods and provides a test case for the accuracy of the predictions. The upper graph of FIG. 2 shows that the distance to the hull stays below 50 meV/atom over all alloy ratios, but also indicates that PZ is predicted as significantly less stable than PT. The lower graph in FIG. 2 indicates a preference for the TET distortion for mixing ratios (1−x)≦0.84.

The results corroborate that the accuracy of the interpolation scheme is sufficient to qualitatively identify PZT as having a crossover point between TET and RHO distortion depending on the ratio of PZ to PT. However, the quantitative accuracy is limited; the crossover point is predicted at (1−x)≈0.840 rather than 0.5 as known for PZT. Furthermore, while PT is predicted to have a zero hull distance, i.e., being thermodynamically stable, a hull distance for pure PZ of ˜40 meV/atom is predicted. Some of this hull distance may be accounted for due to the choice of computing the hull distance for a TET distorted phase. The most stable phase of PZ in the materials project database known at the time of the invention was ˜30 meV/atom above the hull, and the 40-atom cell employed in the analysis should be sufficient to represent the ground state phase. This is a rather large hull distance for a system known to be stable, but is not unreasonable when compared to previous accuracy tests of these methods. The observed hull distance for PZ further motivates the choice of considering combinations of perovskite end points up to as much as 100 meV/atom above the hull at zero temperature.

FIG. 2 depicts the stability (upper graph) and energy preference for a TET distortion (lower graph) in eV/atom for the two component alloy PbTiO₃—PbZrO₃ (PZT). The upper graph shows the energy difference between TET distorted PZT at a specific alloy ratio and the most stable linear combination of any of the possible known competing phases. This graph is consistent with PZT being synthesizable over the whole range, as it stays below 50 meV/atom, and the lower graph indicates that the alloy prefers TET distortion over a significant range of alloy ratios (i.e., the lower graph is >0). The two graphs thus corroborate PZT as highly relevant for piezoelectrics due to the alloy being both possible to synthesize and having a phase boundary between TET and another distortion.

### The BTZC System

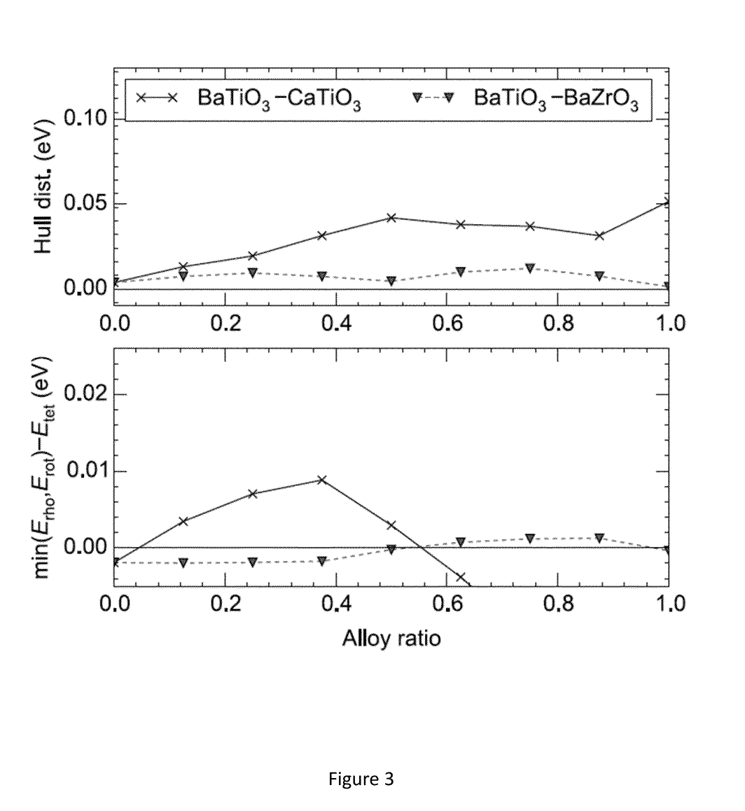

As discussed above, an MPB in the alloy system of BaTiO₃—BaZrO₃—CaTiO₃ has been previously identified. FIG. 3 depicts the calculated stability and distorted phase results for the perovskite alloys of this material. The lower graph of FIG. 3 shows that (BaₓCa₁₋ₓ)TiO₃ is predicted to prefer a TET distortion for mixing ratios (1−x)≦0.58, and for those ratios, the hull distance of the TET distorted phase, as shown in the upper graph, stays below 50 meV/atom. The second perovskite alloy shown in FIG. 3, Ba(TiₓZr₁₋ₓ)O₃ has a small hull distance across all alloy ratios as shown in the upper graph, and weakly prefers the TET distortion at a mixing ratio (1−x)>0.5 and otherwise weakly prefers a non-TET distortion as shown in the lower graph. These results corroborate the preexisting results for the alloy system of BaTiO₃—BaZrO₃—CaTiO₃.

The material may be considered a 4-component solid solution created out of two 2-component end-points. The analysis focuses on the alloy end-point with a TET distortion (i.e., the PT-like material), which in this case is (BaₓCa₁₋ₓ)TiO₃ with a mixing ratio (1−x)=0.3. The results in FIG. 3 is that this is a thermodynamically stable alloy that prefers the TET distortion. The opposite alloy end-point (the PZ-like material) is Ba(TiₓZr₁₋ₓ)O₃ with mixing ratio (1−x)=0.2. The results suggest that this alloy is stable and has a weak non-TET distortion. Thus, an alloy between these two end-points may be a good candidate for a MPB.

FIG. 3 depicts the stability (upper graph) and energy preference for a TET distortion (lower graph) in eV/atom for two component alloys related to the BaTiO₃—BaZrO₃—CaTiO₃ system. The diagram indicates that BaTiO₃—CaTiO₃ may be stable, and prefer a TET distortion, consistent with previously reported characteristics of the alloy system.

(BaₓCa₁₋ₓ)TiO₃ is known to prefer the TET distortion at certain mixing ratios x, despite none of the end-points preferring a TET distortion. This behavior is precisely reproduced by the interpolation scheme, as shown in the lower graph of FIG. 3, and the range for alloys preferring a TET distortion is predicted as 0.02<(1−x)<0.58. These results reproducing the qualitative behavior validate the interpolation scheme. For the CaTiO₃ end-point, the ground state is a highly distorted monoclinic perovskite. The energy difference between this ground state and the TET distortion is quite large and accounts for the instability seen in the hull distance graph for this end-point.

### The KNLNT System

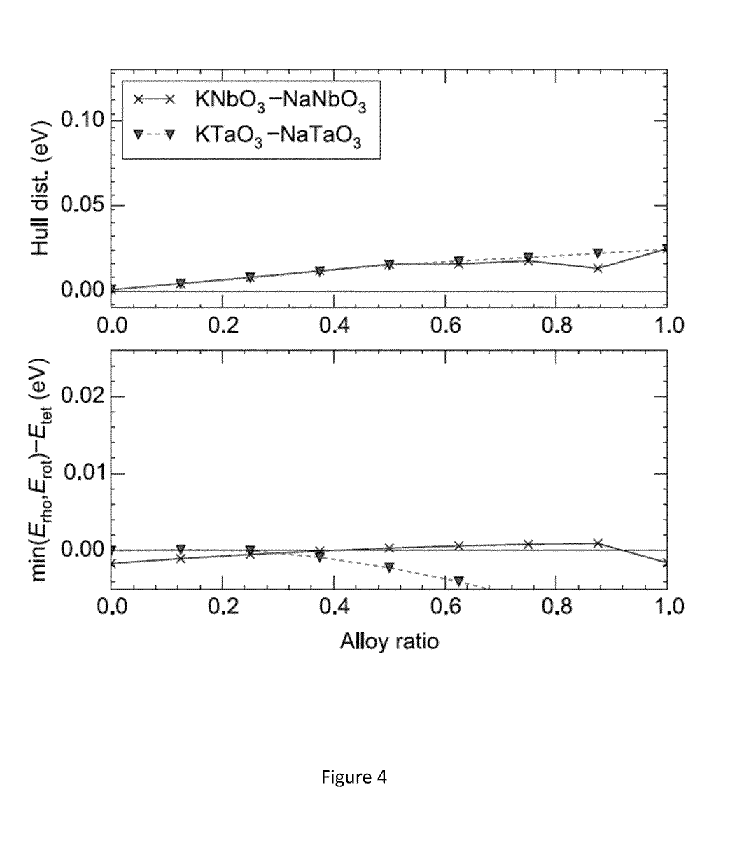

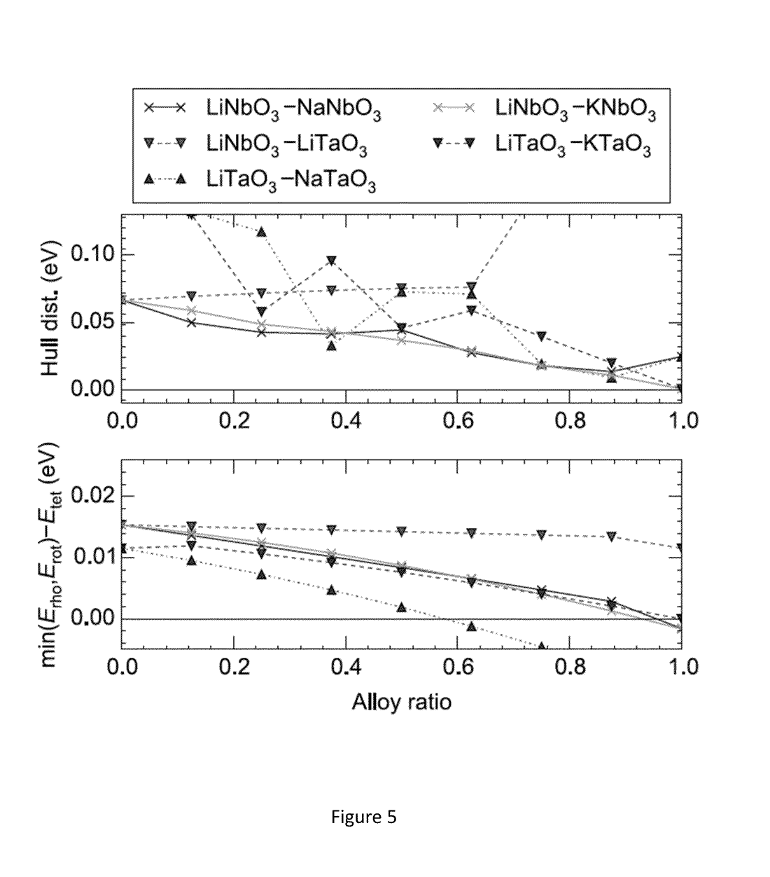

Another previously known alloy system with an MPB is (K, Na, Li)(Nb, Ta)O₃. FIGS. 4 and 5 show the stability and distorted phase results for various two-component alloy systems related to this material. The base component is the (K, Na)(Nb, Ta)O₃ system. According to the hull distance graph depicted in FIG. 4, this alloy has a very small distance to the hull for all mixing ratios. The lower graph in FIG. 4 shows that the TET distortion and the closest competing distortion essentially share the same energy. In FIG. 5 various combinations of one of these end-points and Li are depicted. The lower graph of FIG. 5 indicates a strong trend between Li concentration and a stronger preference for a TET distortion. However, in the hull distance graph of FIG. 5, a higher concentration of Li is shown to increase the hull distance. The reason for this behavior may be the large mismatch of the ion sizes between Li and the other ions. For increasing concentration of Li, the size mismatch makes for a less stable alloy, but also an alloy where the Li ion may be displaced. This ion size mismatch may be observed directly from the end points having very different Goldschmidt parameters.

FIG. 4 depicts the stability (upper graph) and energy preference for a TET distortion (lower graph) in eV/atom for the (K, Na)(Nb, Ta)O₃ system.

FIG. 5 depicts the stability (upper graph) and energy preference for a TET distortion (lower graph) in eV/atom for relevant alloys with Li with the components of the (K, Na)(Nb, Ta)O₃ system. The system becomes less stable as the Li content is increased, and also more strongly prefers the TET distortion.

These results confirm that synthesis of the preexisting (K, Na, Li)(Nb, Ta)O₃ material should strike a balance between Li, which lowers the energy of a tetragonal distortion, with other components that make the alloy thermodynamically stable.

### Other Pb-Based Alloys

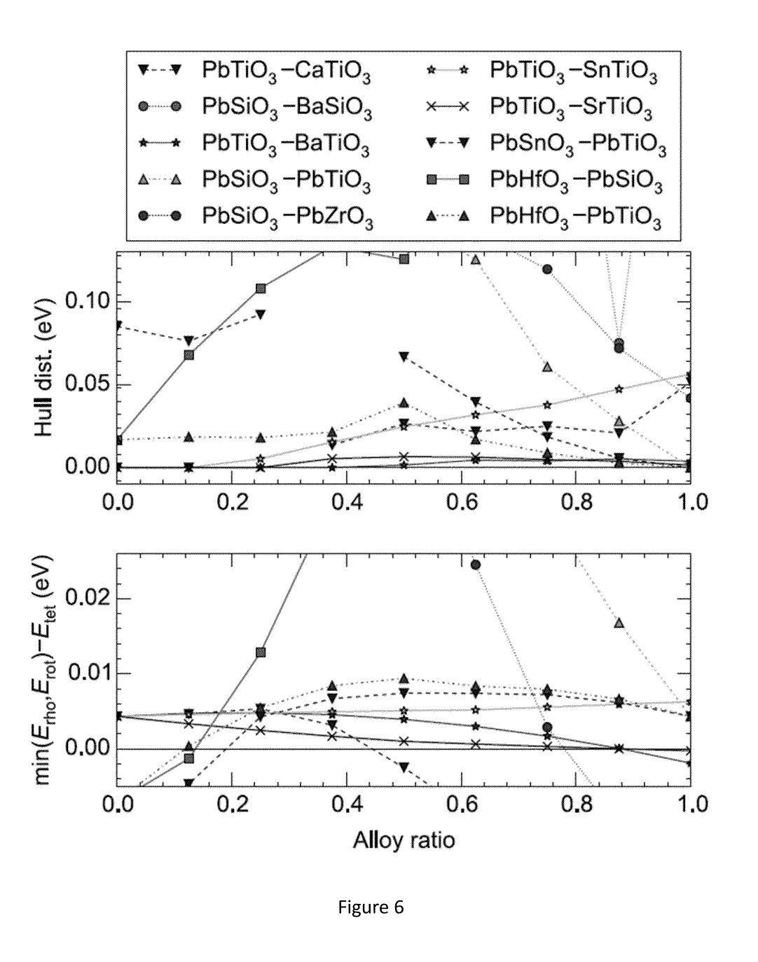

Pb-based alloys are not excluded from the screening analysis, and thus various combinations that include Pb may be identified as producing stable alloys that prefer the TET distortion. For the pursuit of lead-free piezoelectrics these may be of less interest, though, they are possibly relevant for reducing the relative amount of lead in such materials. An overview of the compounds considered in this work is presented in FIG. 6, which includes many alloys comprising Pb that prefer the TET distortion, as shown by most lines in the lower graph being above zero, while simultaneously having comparably small hull distances, i.e., many of the corresponding lines in the hull distance graph are far below 0.5 eV.

FIG. 6. depicts the stability (upper graph) and energy preference for a TET distortion (lower graph) in eV/atom for all two-component alloys that remain after our initial screening which involve Pb (except for PZT, which is shown in FIG. 2). While individual alloys may not be clearly discernible in the graphs, a general trend of these alloys as having small hull distances and TET distortions is shown.

The results suggest that it is common for alloys including Pb to form thermodynamically stable alloys that favor a TET distortion. While this may be an expected conclusion for perovskite oxides, it further bolsters the confidence in the above described screening methods, and suggests the methods may be able to reliably identify such general trends in less studied perovskite families, e.g., nitrides.

### Cu-Based Alloys

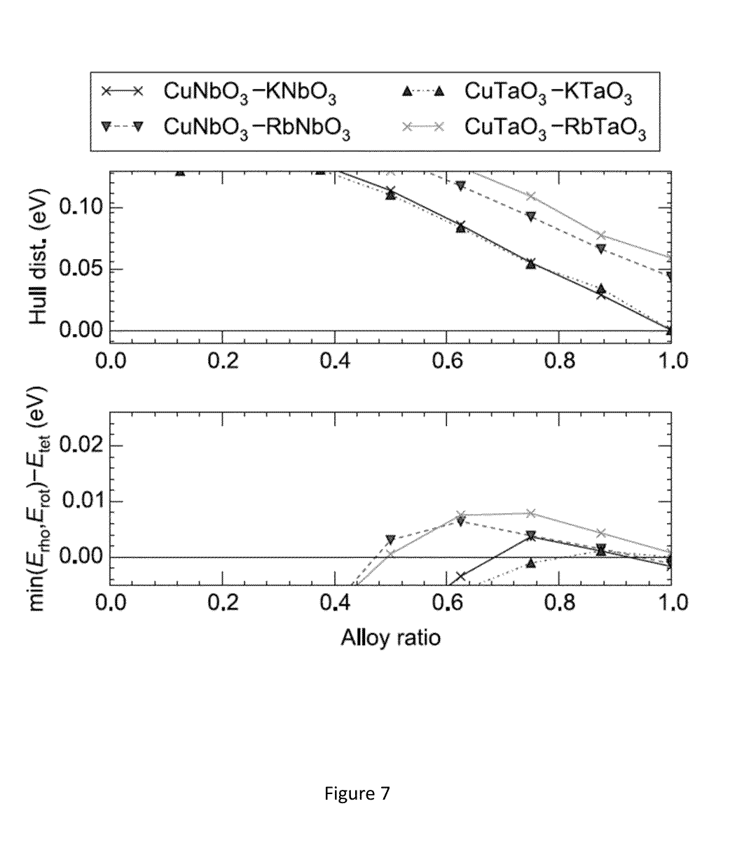

FIG. 7 shows perovskite solid solutions with Cu. The hull distance graph shows that low concentrations of Cu give hull distances below 0.5 eV. The graph over energetics shows that it is also only at low concentrations of Cu that such alloys prefer the TET distortion.

FIG. 7 depicts the stability (upper graph) and energy preference for a TET distortion (lower graph) in eV/atom when Cu is introduced into various perovskites. Small to moderate amounts of Cu appear to make the alloys more strongly prefer the TET distortion, and there may be a region of such substitution into K(Nb, Ta)O₃ with alloys that possibly may be stable in synthesis.

For a system with Cu on the A-site to be stable, it is expected that the multivalent Cu ion will, at least approximately, take a +1 valence to balance the charge between the ions. However, the high instability of configurations with larger amounts of Cu suggests that this configuration is energetically unfavorable. Nevertheless, it may be possible to force the Cu ion into this valence state if the concentration is relatively low relative to a stable end point such as K(Nb, Ta)O₃. Moreover, it appears that a small to moderate amount of Cu on the A-site may push the perovskite structure towards a TET distortion, but at high amounts of Cu the TET distortion may become energetically unfavored. This suggests that an interval of alloy ratios may exist where Cu behaves similar to Li in the KNLNT system. Hence, a desirable alloy may be present in the (CuₓK₁₋ₓ)(Nb, Ta)O₃ alloy system for small values of x.

### Si-Based Alloys

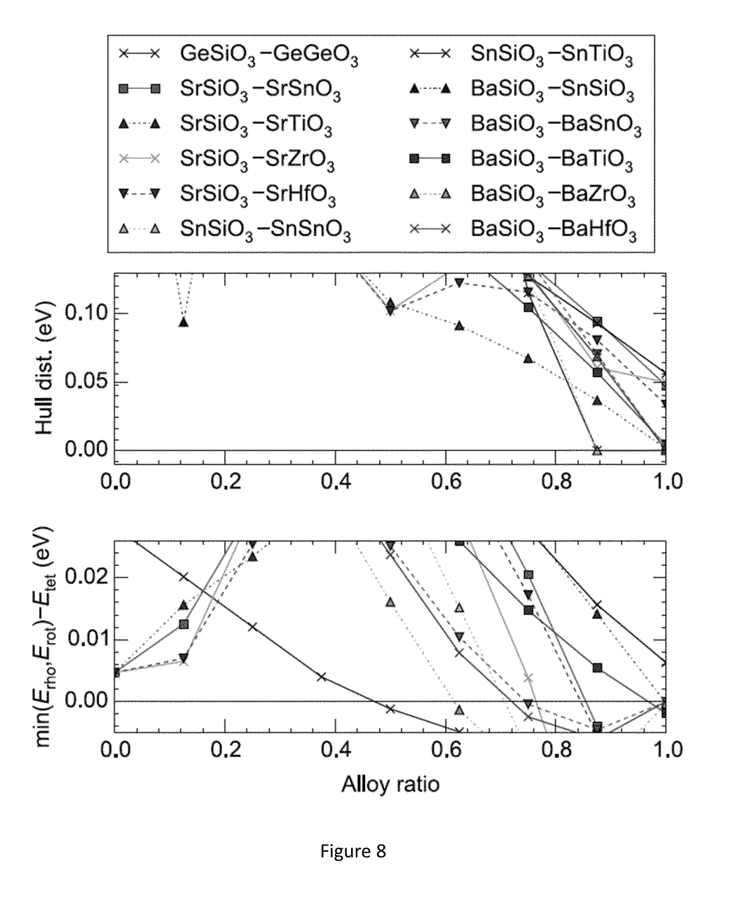

Perovskites with Si or Ge on the B-site, and in particular BaSiO₃, may have promising properties as alloy endpoints. The lower part of FIG. 8 shows that the majority of the Si-based alloys investigated have a moderate to strong preference for a TET distortion. The upper graph of FIG. 8 shows that both the end-points and alloys have large hull distances.

FIG. 8 depicts the stability (upper graph) and energy preference for a TET distortion (lower graph) in eV/atom for two-component alloys involving Si. The Si-based end-points are generally unstable. While individual alloys may not be clearly discernible in the figure, the upper graph shows a general trend of the end-points to not mix well.

Hence, Si-based compounds may demonstrate a preference for a TET distortion. However, it appears these systems are generally not thermodynamically stable in the TET distortion.

### Sn-Based Alloys

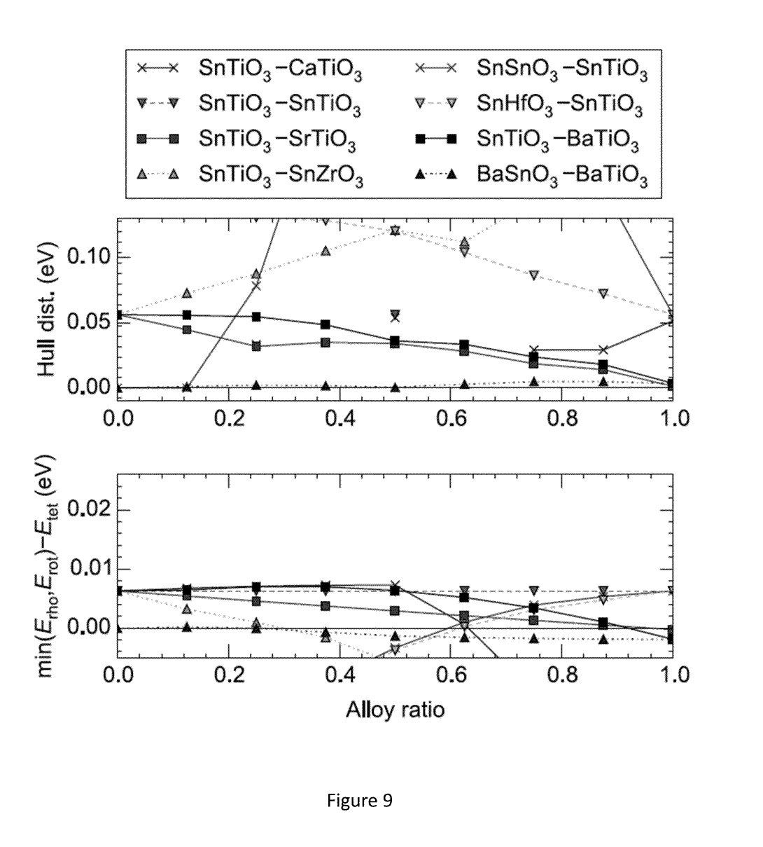

FIG. 9 shows the screening results for Sn based compositions. In general, these compositions behave similarly to the Pb-based alloys discussed above. The lower graph shows many systems as preferring a TET distortion, and the hull distance graph suggests that several systems have comparably small hull distances. In particular, small hull distances are observed for the following alloys, (BaₓSn₁₋ₓ)TiO₃, (SnₓSr₁₋ₓ)TiO₃ and Ba(SnₓTi₁₋ₓ)O₃. The Ba(SnₓTi₁₋ₓ)O₃ alloy includes Sn on the B-site rather than the A-site, and has a significantly smaller hull distance than the other compositions.

FIG. 9 depicts the stability (upper graph) and energy preference for a TET distortion (lower graph) in eV/atom for two-component alloys involving Sn. The alloy (BaₓSn₁₋ₓ)TiO₃ (column 2, row 3 in the legend) stands out as a tetragonal alloy of promising stability, indicating that synthesis may be possible. However, Ba(SnₓTi₁₋ₓ)O₃ (column 2, row 4 in the legend) is more stable and will generally be a readily accessible competing phase in a synthesis attempt of the former alloy.

These results confirm the interest in Sn-based systems. As promising alloys, especially the (BaₓSn₁₋ₓ)TiO₃ alloy with a large x and possibly also (CaₓSn)TiO₃ with x≈0.2, are identified. However, for the former, we note that the lower hull distance of BaSnO₃ indicates that in solid solutions the Sn cations may tend to be present on the B-site in synthesis. On the other hand, the stable (BaₓSn₁₋ₓ)TiO₃ may also be promising. In the interval x≈[0.05, 0.2] the results predict this alloy to (very weakly) prefer a TET distortion. Furthermore, the Ba(HfₓTi₁₋ₓ)O₃ system behaves very similarly, and hence these alloys may be useful in attempts at tuning the BTZC system discussed above.

### Bi-Based Alloys

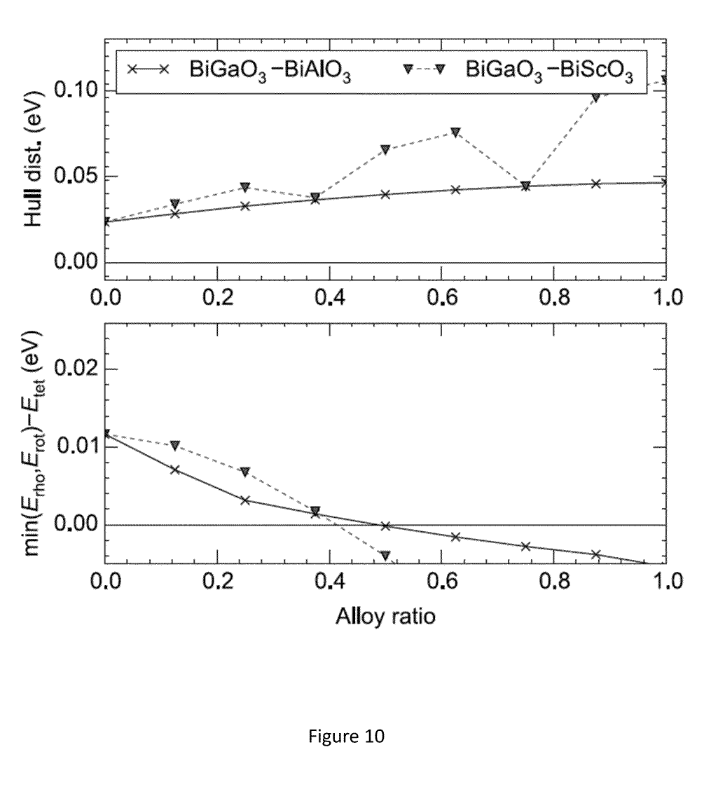

Perovskite alloys with Bi on the A-site were screened. The ones that remain after screening are Bi(GaₓAl₁₋ₓ)O₃ and Bi(GaₓSc₁₋ₓ)O₃. The upper graph of FIG. 10 indicates that both of these alloys have fairly large hull distances. The lower graph of FIG. 10 shows that the TET distortion is preferred if the ratio of Ga is large, i.e., (1−x)<0.5. The preference for a TET distortion for both of these alloys has a composition dependence that resembles that of PZT.

FIG. 10 depicts the stability (upper graph) and energy preference for a TET distortion (lower graph) in eV/atom for two-component alloys including Bi.

### Additional Observations

The screening process serves to identify thermodynamically stable ferroelectric perovskite alloys that prefer a TET distortion. Apart from the individual discussions presented above for each specific group of perovskite alloys, a few general observations about the results and their generality are provided below.

The material (K, Na, Li)(Nb, Ta)O₃, may be considered as starting from a thermodynamically stable composition that does not prefer the TET distortion, K(Nb, Ta)O₃. This system is mixed with (Li)(Nb, Ta)O₃, which prefers the TET distortion but is thermodynamically unstable in perovskite form. Hence, larger amounts of Li may increase the preference for the TET distortion, but also may make the alloy less stable. This mechanism is directly observed in FIG. 5, where an increased concentration of Li correlates both with a higher energy preference for a TET distortion and an increased hull distance. A similar mechanism was identified when a small amount of Cu is introduced in K(Ta, Nb)O₃ as seen in FIG. 7. Since this mechanism only relies on finding an unstable component that strongly prefers the TET distortion, it may be likely to find it in other alloy systems that have not yet been studied, e.g., (oxy-)nitride perovskites, perovskites with rare earth elements, and, possibly, other crystal structures that can accommodate a MPB.

On the other hand, the TET distorted material (Ba,Ca₁₋ₓ)TiO₃ shows a less clear relation between concentration, energy preference for the TET distortion, and hull distance. In this case, two thermodynamically stable materials are mixed, neither of which prefer the TET distortion. The component with the smaller cell volume may make the alloy prefer the TET distortion. This is a very attractive mechanism for creating a TET distorted alloy because it avoids involving an unstable end-point in the alloy and may be easier to synthesize. However, this mechanism has not been identified in any of the other studied 2-component perovskite oxides (possibly excluding some Pb-based systems; note how in FIG. 2 PZT is predicted to have a larger preference for the TET distortion than PT itself).

Additional alloys that have been identified include (Ba₁—Sn₁)Ti₂O₆, (Ba₃—Sn₁)Ti₄O₁₂, (Ba₃—Sn₅)Ti₈O₂₄, Ba₄(Hf₃—Ti₁)O₁₂, (Ba₅—Sn₃)Ti₈O₂₄, (Ba₇—Sn₁)Ti₈O₂₄, Ba₈(Hf₇—Ti₁)O₂₄, Ba₈(Sn₇—Ti₁)O₂₄, Bi₄(Al₁—Ga₃O₁₂, Bi₄(Ga₃—Sc₁)O₁₂, Bi₈(Al₁—Ga₇)O₂₄, Bi₈(Al₃—Ga₅)O₂₄, Bi₈(Ga₅—Sc₃)O₂₄, Bi₈(Ga₇—Sc₁)O₂₄, (Ca₁—Sn₃)Ti₄O₁₂, (Cs₁—Na₇)Nb₈O₂₄, (Cu₁—K₇)Nb₈O₂₄, Cu₁—K₇)Ta₈O₂₄, (Ga₁—K₃)Ta₄O₁₂, (K₁—Rb₁)Ta₂O₆, (K₁—Rb₃)Ta₄O₁₂, (K₁—Tl₁)Ta₂O₆, (K₃—Rb₅)Ta₈O₂₄, (K₃—Tl₁)Ta₄O₁₂, (K₅—Rb₃)Ta₈O₂₄, (K₅—Tl₃)Ta₈O₂₄, (Li₁—Rb₇)Nb₈O₂₄, (Na₅—Rb₃)Nb₈O₂₄, (Sn₁—Sr₁)Ti₂O₆, (Sn₁—Sr₃)Ti₄O₁₂, (Sn₁—Sr₇)Ti₈O₂₄, (Sn₃—Sr₁)Ti₄O₁₂, (Sn₃—Sr₅)Ti₈O₂₄, (Sn₅—Sr₃)Ti₈O₂₄, (Sn₇—Sr₁)Ti₈O₂₄, and Sr₈(Si₁—Ti₇)O₂₄.

A large-scale high-throughput DFT framework has been utilized in the methods described herein to investigate an extensive space of perovskite alloys. The investigation has focused on identifying two-component alloys with a ground state TET distortion, i.e., candidates for the primary component in a system with a MPB that most prominently combine a preference towards a TET distortion with stability are alloys which have already been used or proposed for high-performance piezoelectrics. However, promising less studied systems have herein been identified. In particular, K(Ta, Nb)O₃ with a small amount of Cu, and BiGaO₃ with small amounts of Sc or Al. (Ba, Sn)-based titanates are also confirmed to be promising piezoelectric materials.

The above described interpolation scheme successfully describes the energetics of distorted phases of isovalent alloys with sufficient accuracy to identify materials with a specific ground state distortion. The results point at the space of oxide perovskites as mostly exhausted for novel MPB systems. The screening method may be extended into into less experimentally explored perovskite systems, e.g., (oxy-)nitrides, perovskites with rare-earth elements, or even to identify MPBs in other crystal structures. The methods provided herein are more efficient than pre-existing screening techniques and do not need to rely on determination of piezoelectric coefficients for screening in at least one embodiment.

In high-throughput material design, it is a major challenge to handle alloy systems, since they can quickly lead to very extensive chemical spaces. The screening method presented herein demonstrates a way to predict the energetics of distorted phases of isovalent alloys that avoids extensive brute-force computational work that would be prohibitively time consuming. The discussed approach may also be very useful also for high-throughput material design in other areas. It is noted that any of the suitable processes involved in the methods provided herein may be performed by a processor, such as that of a computer, configured specifically to perform the processes. In one embodiment, some of the processes involved in the methods provided herein, particularly those that involve a processor, may be performed by the processor as a result of execution of the processor by an algorithm in a software. The software may be stored in a non-transitory computer-readable medium.

### Additional Notes

All literature and similar material cited in this application, including, but not limited to, patents, patent applications, articles, books, treatises, and web pages, regardless of the format of such literature and similar materials, are expressly incorporated by reference in their entirety. In the event that one or more of the incorporated literature and similar materials differs from or contradicts this application, including but not limited to defined terms, term usage, described techniques, or the like, this application controls.

While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

While various inventive embodiments have been described and illustrated herein, those of ordinary skill in the art will readily envision a variety of other mechanisms and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments of the invention may be implemented in any of numerous ways. For example, some embodiments may be implemented using hardware, software or a combination thereof. When any aspect of an embodiment is implemented at least in part in software, the software code may be executed on any suitable processor or collection of processors, whether provided in a single computer or distributed among multiple computers.

In this respect, various aspects of the invention may be embodied at least in part as a computer readable storage medium (or multiple computer readable storage media) (e.g., a computer memory, one or more floppy discs, compact discs, optical discs, magnetic tapes, flash memories, circuit configurations in Field Programmable Gate Arrays or other semiconductor devices, or other tangible computer storage medium or non-transitory medium) encoded with one or more programs that, when executed on one or more computers or other processors, perform methods that implement the various embodiments of the technology discussed above. The computer readable medium or media may be transportable, such that the program or programs stored thereon may be loaded onto one or more different computers or other processors to implement various aspects of the present technology as discussed above.

The terms “program” or “software” are used herein in a generic sense to refer to any type of computer code or set of computer-executable instructions that may be employed to program a computer or other processor to implement various aspects of the present technology as discussed above. Additionally, it should be appreciated that according to one aspect of this embodiment, one or more computer programs that when executed perform methods of the present technology need not reside on a single computer or processor, but may be distributed in a modular fashion amongst a number of different computers or processors to implement various aspects of the present technology.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, the technology described herein may be embodied as a method, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.” Any ranges cited herein are inclusive.

The terms “substantially” and “about” used throughout this Specification are used to describe and account for small fluctuations. For example, they may refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” may refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

The claims should not be read as limited to the described order or elements unless stated to that effect. It should be understood that various changes in form and detail may be made by one of ordinary skill in the art without departing from the spirit and scope of the appended claims. All embodiments that come within the spirit and scope of the following claims and equivalents thereto are claimed.

What is claimed:

1. A piezoelectric material comprising at least one of (Ba₁—Sn₁)Ti₂O₆, (Ba₃—Sn₁)Ti₄O₁₂, (Ba₃—Sn₅)Ti₈O₂₄, Ba₄(Hf₃—Ti₁)O₁₂, (Ba₅—Sn₃)Ti₈O₂₄, (Ba₇—Sn₁)Ti₈O₂₄, Ba₈(Hf₇—Ti₁)O₂₄, Ba₈(Sn₇—Ti₁)O₂₄, Bi₄(Al₁—Ga₃)O₁₂, Bi₄(Ga₃—Sc₁)O₁₂, Bi₈(Al₁—Ga₇)O₂₄, Bi₈(Al₃—Ga₅)O₂₄, Bi₈(Ga₅—Sc₃)O₂₄, Bi₈(Ga₇—Sc₁)O₂₄, (Ca₁—Sn₃)Ti₄O₁₂, (Cs₁—Na₇)Nb₈O₂₄, (Cu₁—K₇)Nb₈O₂₄, (Cu₁—K₇)Ta₈O₂₄, (Ga₁—K₃)Ta₄O₁₂, (K₁—Rb₁)Ta₂O₆, (K₁—Rb₃)Ta₄O₁₂, (K₁—Tl₁)Ta₂O₆, (K₃—Rb₅)Ta₈O₂₄, (K₃—Tl₁)Ta₄O₁₂, (K₅—Rb₃)Ta₈O₂₄, (K₅—Tl₃)Ta₈O₂₄, (Li₁—Rb₇)Nb₈O₂₄, (Na₅—Rb₃)Nb₈O₂₄, (Sn₁—Sr₁)Ti₂O₆, (Sn₁—Sr₃)Ti₄O₁₂, (Sn₁—Sr₇)Ti₈O₂₄, (Sn₃—Sr₁)Ti₄O₁₂, (Sn₃—Sr₅)Ti₈O₂₄, (Sn₅—Sr₃)Ti₈O₂₄, (Sn₇—Sr₁)Ti₈O₂₄, and Sr₈(Si₁—Ti₇)O₂₄.

2. The material of claim 1, wherein the material comprises a perovskite structure.

3. The material of claim 1, wherein the material is lead free.

4. The material of claim 1, wherein the material is capable of accommodating a morphotrophic phase boundary.

5. The material of claim 1, wherein the material has a Kohn-Sham band gap of greater than about 0.25 eV.

6. The material of claim 1, wherein the material has a tetragonal ground state.

7. The material of claim 1, wherein a distortion energy of an ideal perovskite cell of the material satisfies the following equation:
max(E_{ROT}, E_{TET}, E_{RHO})−min(E_{ROT}, E_{TET}, E_{RHO}))<1.00 eV,
wherein E_{ROT} is the energy of an alternating clockwise and anticlockwise octahedral rotation distortion around the (1, 1, 1) direction, E_{TET} is the energy of a tetragonal distortion, and E_{RHO} is the energy of a rhombohedral distortion.

8. The material of claim 1, wherein the material comprises a phase with a distance to the hull of less than about 0.1 eV/atom.

9. The material of claim 1, wherein the material has a Kohn-Sham band gap less than or equal to about 0.25 eV.

10. A method comprising:
calculating, using at least one computer, a distance to a hull for an alloy XₓY₁₋ₓ in the range 0.01≦x≦0.99, where X and Y are perovskite materials;
determining, using the at least one computer, a preferred phase for the alloy in the range 0.01≦x≦0.99; and
selecting an alloy composition having the distance to the hull being less than 0.1 eV/atom and for which the preferred phase in at least a portion of the range 0.01≦x≦0.99 is a tetragonal phase.

11. The method of claim 10, wherein the selecting further comprises excluding compositions with a Kohn-Sham band gap greater than 0.25 eV.

12. The method of claim 10, wherein the selecting further comprises excluding compositions wherein a distortion phase energy of an ideal perovskite cell of the composition does not satisfy the following equation:
max(E_{ROT}, E_{TET}, E_{RHO})−min(E_{ROT}, E_{TET}, E_{RHO})<1.00 eV,
wherein E_{ROT} is the energy of an alternating clockwise and anticlockwise octahedral rotation distortion around the (1, 1, 1) direction, E_{TET} is the energy of a tetragonal distortion, and E_{RHO} is the energy of a rhombohedral distortion.

13. The method of claim 10, wherein the determining the preferred phase further comprises:
estimating a unit cell volume V of the alloy XₓY₁₋ₓ by linear interpolation from respective unit cell volumes of X and Y;
constructing a piecewise linear energy vs. volume curve for end points X and Y;
calculating distorted phase energies at the unit cell volume Von a basis of the constructed linear energy vs. volume curve; and
interpolating linearly the distorted phase energies at the unit cell volume V to alloy ratio x to estimate the phase energies of the alloy XₓY₁₋ₓ in the range 0.01≦x≦0.99.

14. The method of claim 13, further comprising calculating distorted phase energies for the unit cell volume Vat 45 angstroms to 90 angstroms.

15. The method of claim 10, further comprising producing the selected alloy composition.

16. The method of claim 10, wherein the selected alloy composition is lead free.

17. The method of claim 10, wherein the selected alloy composition is capable of accommodating a morphotrophic phase boundary.

18. The method of claim 10, wherein the selected alloy composition comprises K(Ta,Nb)O₃ with Cu; BiGaO₃ with Sc or Al; and (Ba,Sn)-based titanates.

19. The method of claim 10, wherein the selected alloy composition comprises at least one of (Ba₁—Sn₁)Ti₂O₆, (Ba₃—Sn₁)Ti₄O₁₂, (Ba₃—Sn₅)Ti₈O₂₄, Ba₄(Hf₃—Ti₁)O₁₂, (Ba₅—Sn₃)Ti₈O₂₄, (Ba₇—Sn₁)Ti₈O₂₄, Ba₈(Hf₇—Ti₁)O₂₄, Ba₈(Sn₇—Ti₁)O₂₄, Bi₄(Al₁—Ga₃)O₁₂, Bi₄(Ga₃—Sc₁)O₁₂, Bi₈(Al₁—Ga₇)O₂₄, Bi₈(Al₃—Ga₅)O₂₄, Bi₈(Ga₅—Sc₃)O₂₄, Bi₈(Ga₇—Sc₁)O₂₄, (Ca₁—Sn₃)Ti₄O₁₂, (Cs₁—Na₇)Nb₈O₂₄, (Cu₁—K₇)Nb₈O₂₄, (Cu₁—K₇)Ta₈O₂₄, (Ga₁—K₃)Ta₄O₁₂, (K₁—Rb₁)Ta₂O₆, (K₁—Rb₃)Ta₄O₁₂, (K₁—Tl₁)Ta₂O₆, (K₃—Rb₅)Ta₈O₂₄, (K₃—Tl₁)Ta₄O₁₂, (K₅—Rb₃)Ta₈O₂₄, (K₅ —Tl₃)Ta₈O₂₄, (Li₁—Rb₇)Nb₈O₂₄, (Na₅—Rb₃)Nb₈O₂₄, (Sn₁—Sr₁)Ti₂O₆, (Sn₁—Sr₃)Ti₄O₁₂, (Sn₁—Sr₇)Ti₈O₂₄, (Sn₃—Sr₁)Ti₄O₁₂, (Sn₃—Sr₅)Ti₈O₂₄, (Sn₅—Sr₃)Ti₈O₂₄, (Sn₇—Sr₁)Ti₈O₂₄, and Sr₈(Si₁—Ti₇)O₂₄.

20. The method of claim 10, wherein the alloy is an isovalent alloy system.
